(19) United States
(12) Patent Application Publication
(10) Pub. No.: US 2025/0180987 A1
(43) Pub. Date: Jun. 5, 2025

(54) DRY DEVELOPMENT FOR METAL-OXIDE PHOTO RESISTS

(71) Applicant: Applied Materials, Inc., Santa Clara, CA (US)

(72) Inventors: NASRIN KAZEM, Santa Clara, CA (US); NIRANJANA BALESAN, Fremont, CA (US); MADHUR SACHAN, Belmont, CA (US); NANCY FUNG, Livermore, CA (US); KAI NG, Santa Clara, CA (US); SHASHANK SHARMA, Sunnyvale, CA (US)

(21) Appl. No.: 18/941,232

(22) Filed: Nov. 8, 2024

Related U.S. Application Data
(60) Provisional application No. 63/605,389, filed on Dec. 1, 2023.

(51) Int. Cl. G03F 7/004; G03F 7/16

(52) U.S. Cl. CPC G03F 7/0043; G03F 7/167

(57) ABSTRACT

Embodiments described herein relate to a method for developing a resist layer that includes tin and oxygen with an exposed region and an unexposed region. In an embodiment, the includes applying a surface treatment to the resist layer, where the surface treatment incorporates fluorine into the unexposed region. In an embodiment, the method further includes developing the resist layer with a dry develop process that includes a source gas including hydrogen, where the developed resist layer has an opening through the resist layer.

### CROSS-REFERENCE TO RELATED APPLICATIONS

This application claims the benefit of U.S. Provisional Application No. 63/605,389, filed on Dec. 1, 2023, the entire contents of which are hereby incorporated by reference herein.

### BACKGROUND

### 1) Field

Embodiments relate to the field of semiconductor manufacturing and, in particular, to dry develop processes for metal-oxide resists that use a hydrogen source gas.

2) Description of Related Art

Extreme ultra violet (EUV) patterning has been growing in importance in semiconductor manufacturing due to the ability to pattern resists with smaller feature sizes (e.g., critical dimensions (CDs)). However, EUV lithography processes currently use resist layers that suffer from low absorbance of the EUV radiation. As such, higher doses, longer exposure times, and/or thinner resist layers are needed in order to develop the necessary chemical contrast between exposed and unexposed regions. One class of resist material that have been shown to improve absorbance of the EUV radiation is metal-oxide based resist layers.

Typically, metal-oxide systems are developed using a wet etching chemistry. However, the wet etching chemistry interacts with the resist layer at the cluster level, so the partially exposed resist at the edges might or might not be dissolved. So there is a resolution limit imposed by the cluster size of the resist. This can lead to high line width roughness (LWR), which negatively impacts pattern transfer into the underlying substrate.

### SUMMARY

Embodiments described herein relate to a method for developing a resist layer that includes tin and oxygen with an exposed region and an unexposed region. In an embodiment, the includes applying a surface treatment to the resist layer, where the surface treatment incorporates fluorine into the unexposed region. In an embodiment, the method further includes developing the resist layer with a dry develop process that includes a source gas including hydrogen, where the developed resist layer has an opening through the resist layer.

Embodiments described herein relate to a method for developing a resist layer that includes a metal and oxygen, where the resist layer includes an exposed region and an unexposed region that includes fluorine. In an embodiment, the method includes developing the resist layer with a dry process that includes a hydrogen source gas, and where the developing removes the unexposed region to form an opening through a thickness of the resist layer.

Embodiments described herein relate to a non-transitory computer readable medium including instructions that, when executed by at least one processor, cause a processing tool to perform a method for developing a resist layer that includes a metal and oxygen with an exposed region and an unexposed region. In an embodiment, the method includes applying a surface treatment to the resist layer, where the surface treatment incorporates fluorine into the unexposed region. In an embodiment, the method further includes developing the resist layer with a dry develop process that includes a source gas including hydrogen, where the developed resist layer has an opening through the resist layer.

### BRIEF DESCRIPTION OF THE DRAWINGS

FIG. 1A is a cross-sectional illustration of a portion of a substrate with a patterned resist layer that exhibits high line width roughness (LWR), in accordance with an embodiment.

FIG. 1B is a cross-sectional illustration of a portion of a substrate with a patterned resist layer that exhibits lower LWR due to the use of a dry develop process, in accordance with an embodiment.

FIGS. 2A-2D are cross-sectional illustrations depicting a process for developing a metal-oxide resist with a dry develop process that comprises a hydrogen source gas, in accordance with an embodiment.

FIGS. 3A-3D are cross-sectional illustrations depicting a process for developing a metal-oxide resist with a surface treatment and a dry develop process that comprises a hydrogen source gas, in accordance with an embodiment.

FIG. 4 is a process flow diagram of a process for developing a metal-oxide resist layer with a dry develop process, in accordance with an embodiment.

FIG. 5 is a process flow diagram of a process for developing a metal-oxide resist layer with a surface treatment and a dry develop process that comprises a hydrogen source gas, in accordance with an embodiment.

FIG. 6A is a cross-sectional illustration of a thermal chamber for developing a metal-oxide resist layer, in accordance with an embodiment.

FIG. 6B is a cross-sectional illustration of a plasma chamber for developing a metal-oxide resist layer, in accordance with an embodiment.

FIG. 7 illustrates a block diagram of an exemplary computer system that may be used in conjunction with a processing tool, in accordance with an embodiment.

### DETAILED DESCRIPTION

Systems described herein include dry develop processes for metal-oxide resists that use a hydrogen source gas. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

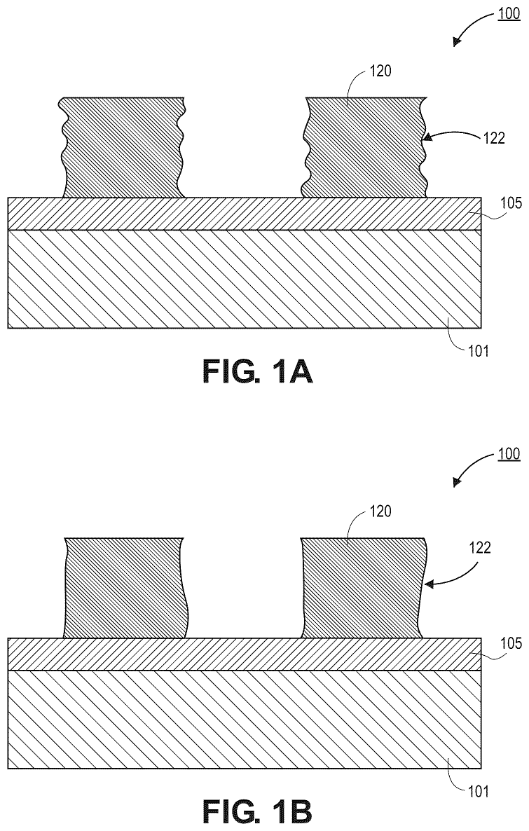

As noted above, metal-oxide resists are an emerging photoresist material system that can improve the absorbance of extreme ultra violet (EUV) radiation. While wet development processes can be used, such processes are often limited by high line width roughness (LWR). An example of such a system is shown in FIG. 1A.

Referring now to FIG. 1A, a cross-sectional illustration of a stack 100 is shown, in accordance with an embodiment. The stack 100 may comprise a substrate 101. The substrate 101 may comprise one or more of a semiconductor material (e.g., silicon or the like), a metallic material, a dielectric material, or the like. An underlayer 105 may be provided over the substrate 101. The underlayer 105 may comprise one or more of an antireflective coating (ARC), a hardmask material, a dielectric, or the like. In an embodiment, a developed resist layer 120 may be provided over the underlayer 105. The resist layer 120 may be a metal-oxide resist material.

In the particular embodiment shown in FIG. 1A, the resist layer 120 may be developed with a wet develop process. That is, a wet etching chemistry may be used to remove either exposed or unexposed regions in order to leave behind a pattern of the resist layer 120. As noted above, the use of a wet etching process has limitations in that a roughness of the sidewall 122 is high. This may be due, at least in part, to the developing solution interacting at the cluster level. A cluster may refer to a metal element center that is coupled to (e.g., chemically coupled to) oxygen and/or any other elements. These clusters may be relatively large, and can lead to significant LWR penalties. The high roughness may be detrimental to subsequent pattern transfer into the substrate 101.

Accordingly, some embodiments may rely on a dry develop process in order to improve the LWR of the patterned resist 120. An example of such an embodiment is shown in FIG. 1B. As shown, the LWR of the resist 120 in FIG. 1B is lower than that of FIG. 1A. More generally, the sidewall 122 in FIG. 1B is closer to a vertical line than what is shown in FIG. 1A. This may be due, at least in part, to the dry developing process attacking the resist 120 at the atomic level instead of the cluster level. As such, LWR has a lower dependence (or no dependence) on the size of the clusters.

Dry develop process may be thermal based processes or plasma based processes. In a thermal process, a source gas is flown into the chamber, and the source gas etches the exposed or unexposed regions. In a plasma process, a source gas is flown into the chamber and ionized. Radical and/or ionic species of the source gas may then contribute to the etching of the resist.

In existing dry etching processes, the source gasses are typically halogen based. For example, HBr and HCl are typical for dry development processes of metal-oxide resist systems. However, halogen based chemistries generate concerns regarding the introduction of new elemental contaminations into the system. For example, the halogen species can integrate into the developed resist 120. It is believed that hydrogen bonding traps acidic halides into the cluster. These acidic halides can outgas over time, which can be detrimental to subsequent processing and/or to the cleanliness of the processing tools/environments.

Accordingly, embodiments disclosed herein may utilize a cleaner processing gas that avoids trapping species in the resist 120 that can outgas over time. For example, a pure hydrogen gas (e.g., H₂) can be used in some embodiments. The hydrogen gas can react with the unexposed regions of the resist 120 in order to develop the resist 120 without the threat of subsequent outgassing. In some embodiments, additional non-reactive and/or inert gasses may be flown with the hydrogen gas, such as one or more of nitrogen, xenon, argon, or the like.

In one embodiment, the dry develop process with a hydrogen source gas is a thermal process. Control of one or more processing parameters (e.g., substrate temperature, pressure, gas flow rates, etc.) can be used to set a desired contrast that enables proper development of the resist 120. In another embodiment, the dry develop process with a hydrogen source gas is a plasma based process. In such an embodiment, the plasma ionizes the hydrogen and ions and/or radicals contribute to the etching of the resist 120. In some embodiments a combination of thermal and plasma process may be used in order to develop the resist 120.

In an embodiment, the resist 120 may be developed after exposure. In other embodiments, a surface treatment may be applied to the resist 120 before developing. The surface treatment may increase etch selectivity between the exposed regions and the unexposed regions of the resist 120. In one embodiment, the surface treatment may be a fluorination treatment.

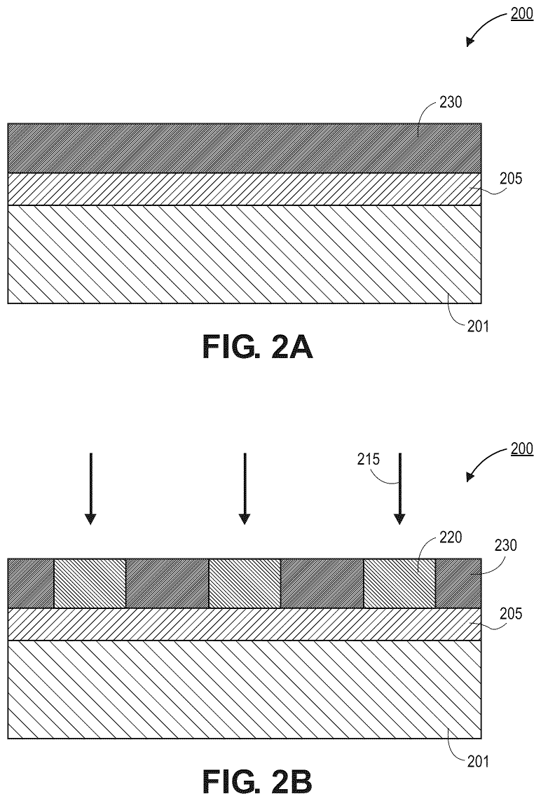

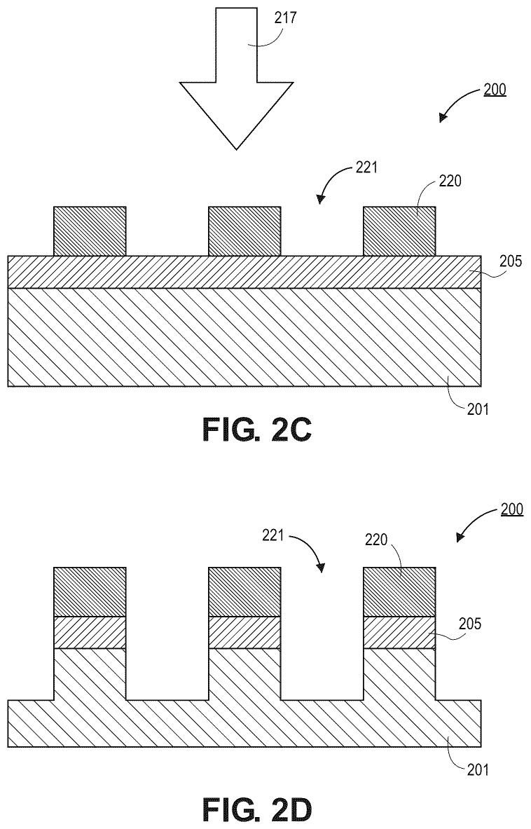

Referring now to FIGS. 2A-2D, a series of cross-sectional illustrations depicting a process for using photolithography to transfer a pattern from a resist into an underlying substrate is shown, in accordance with an embodiment. The embodiment, shown in FIGS. 2A-2D includes an exposure of the resist layer followed by a dry developing process. As will be described in greater detail below, the dry developing process may include one or both of a plasma process or a thermal process.

Referring now to FIG. 2A, a cross-sectional illustration of a stack 200 is shown, in accordance with an embodiment. The stack 200 may comprise a substrate 201. The substrate 201 may comprise one or more of a semiconductor material (e.g., silicon or the like), a metallic material, a dielectric material, or the like. The substrate 201 may be part of a wafer (e.g., a 300 mm wafer, or the like), or the substrate 201 may have any other form factor. An underlayer 205 may be provided over the substrate 201. The underlayer 205 may comprise one or more of an ARC, a hardmask material, a dielectric, or the like.

In an embodiment, a resist layer 230 is provided over the underlayer 205. The resist layer 230 may be a photoimageable material. Upon exposure to electromagnetic radiation, the resist layer 230 undergoes a chemical change in the exposed regions. The chemical difference between the exposed regions and the unexposed regions generates an etch selectivity that can be used to develop the resist layer 230. In a particular embodiment, the resist layer 230 is tuned to absorb and react to exposure from EUV radiation. Any suitable EUV compatible material composition may be used for the resist layer 230. For example, the resist layer 230 may comprise a metal-oxide material. The metal element of the metal-oxide material may comprise tin. Though, other metallic elements, or a combination of two or more different metallic elements may be used to form the metal-oxide material. The metal-oxide material may further comprise other elements, such as oxygen, carbon, hydrogen, or the like.

The resist layer 230 may be applied over the underlayer 205 with any suitable process. In some instances, the resist layer 230 is a flowable material (e.g., a liquid or semi-liquid) that can be deposited with a spin-on process or the like. In other embodiments, the resist layer 230 is applied with a dry deposition process. For example, a chemical vapor deposition (CVD) process, an atomic layer deposition (ALD) process, or a physical vapor deposition (PVD) process may be used to deposit the resist layer 230 over the underlayer 205.

Referring now to FIG. 2B, a cross-sectional illustration of the stack 200 at a subsequent processing operation is shown, in accordance with an embodiment. FIG. 2B illustrates the exposure of the resist layer 230. In an embodiment, electromagnetic radiation 215 (e.g., EUV radiation, deep ultra violet (DUV) radiation, ultra violet (UV) radiation, or the like) is used to expose portions of the resist layer 230. The electromagnetic radiation 215 can be selectively directed to exposed regions 220 of the resist layer 230 through any number of radiation focusing or masking processes. For example, a mask or reticle may be used to allow the electromagnetic radiation 215 to pass to only the exposed regions 220. Scanning exposure tools, stepping exposure tools, beams of electromagnetic radiation 215, and/or the like may also be used in order to generate the exposed regions 220.

In the case of a metal-oxide resist layer 230 and EUV electromagnetic radiation 215, the absorption of the EUV electromagnetic radiation 215 may be improved compared to resist layers 230 with compositions from other material classes. Due to the chemical reaction, the exposed regions 220 may be rendered more chemically inert than the remainder of the unexposed resist layer 230. As such, the subsequent dry develop process can be used to selectively remove the unexposed resist layer 230 since it is more chemically reactive.

Referring now to FIG. 2C, a cross-sectional illustration of the stack 200 at a subsequent processing operation is shown, in accordance with an embodiment. FIG. 2C illustrates the dry develop of the resist layer 230. As shown, a dry develop process 217 is executed, as indicated by the arrow. The dry develop process 217 may include one or more different types of treatments.

In a first embodiment, the dry develop process 217 is a thermal process. That is, a process gas is flown into a chamber (not shown) at an elevated temperature in order to drive a reaction that selectively removes the unexposed resist layer 230. The pressure and temperature within the chamber can also be controlled in order to obtain a desired etching performance. This leaves behind a pattern 221 that can subsequently be transferred into the underlying substrate 201.

In an additional embodiment, the dry develop process 217 is a plasma based process. In a plasma process, the process gas is flown into a chamber (not shown) and ionized. The resulting ionic and/or radical species may react with the unexposed resist layer 230 in order to form the pattern consisting of the exposed regions 220. The plasma process may be modulated through the control of one or more of temperature, pressure, bias, or the like. Depending on the desired result, the plasma process may be further controlled through the use of plasma doping (PLAD) ion implantation. Such additions to the plasma process may slow an otherwise aggressive etching process.

In yet another embodiment, a hybrid process that combines the use of a thermal process and a plasma process may be used in order to develop the resist layer 230. For example, the plasma may be pulsed. While on, the generation of ions and radicals may dominate the etching process. While off, thermodynamic conditions may drive reaction between the process gas and the resist layer 230.

In an embodiment the processing gas (for either a plasma based process, a thermal process, or a hybrid process) may comprise hydrogen (e.g., H₂). In some embodiments, the processing gas comprises only hydrogen. That is, other species (e.g., halides) are omitted from the developing process. This prevents the incorporation of additional elements into the exposed regions 220. As such, outgassing is mitigated or eliminated in subsequent processing operations. In an embodiment, the developing reaction produces volatile species that can be pumped out of the chamber. For example, when the metal-oxide material comprises tin, the volatile species may include SnH₄ and H₂O.

Generally, a plasma based developing process with hydrogen is more aggressive than a thermal developing process with hydrogen. In order to provide the desired etching profile, the aggressiveness of the plasma based process is reduced, and the aggressiveness of the thermal based process is increased. Pressures for use in plasma based developing processes and/or thermal developing processes may be up to approximately 550 Torr, and temperatures (e.g., substrate temperatures) may be up to approximately 300° C.

One way to reduce the aggressiveness of a plasma process is to flow additional processing gasses into the chamber with the hydrogen. In order to minimize negative effects of outgassing, non-reactive and/or inert gasses are used. For example hydrogen and one or more of nitrogen, xenon, and argon may be flown into the chamber. Ion and/or radical filtration may also be used to slow down the reaction rate in a plasma based process.

Referring now to FIG. 2D, a cross-sectional illustration of the stack 200 at a subsequent processing operation is shown, in accordance with an embodiment. FIG. 2D illustrates the transfer of the pattern 221 into the substrate 201. In an embodiment, the pattern 221 may be transferred into the substrate 201 by an etching process. A first etching process may remove portions of the underlayer 205, and a second etching process may remove portions of the substrate 201. The etching processes may use a dry etching chemistry (e.g., plasma based processes) or wet etching chemistry.

In the case of a dry etching chemistry, embodiments may include using a single chamber (not shown) for the resist developing and the substrate etching. For example, a first plasma chemistry may be used for developing the resist layer 230 (e.g., a hydrogen based plasma), and a second plasma chemistry may be used to etch the underlayer 205 and/or the substrate 201. This allows for fewer transfers of the substrate 201 between tools, and can increase throughput. Minimizing transfer of the substrate 201 can also reduce defect generation (e.g., by preventing particles or the like from depositing on the stack 200).

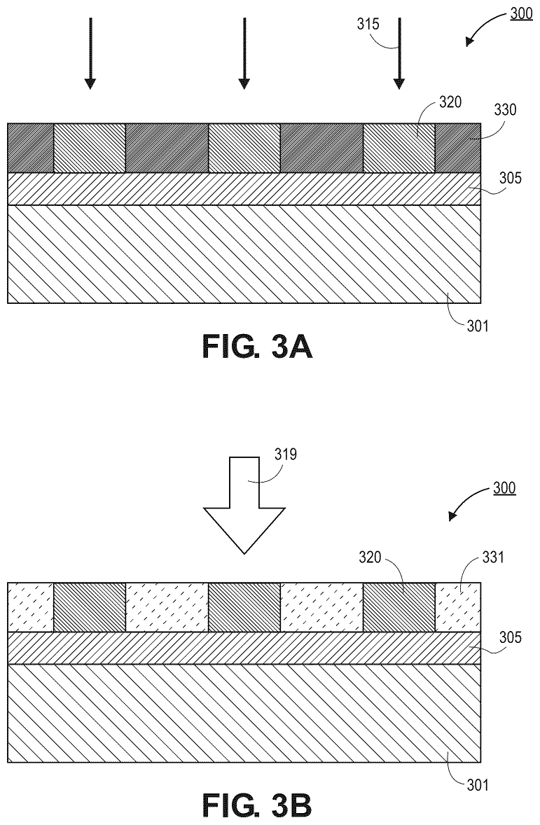

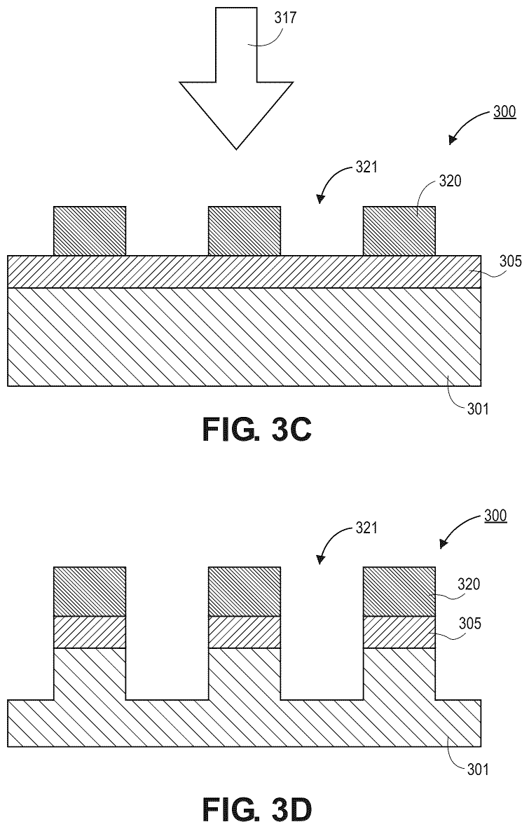

Referring now to FIGS. 3A-3D, a series of cross-sectional illustrations depicting a process for using photolithography to transfer a pattern from a resist into an underlying substrate is shown, in accordance with an embodiment. The embodiment, shown in FIGS. 3A-3D includes an exposure of the resist layer followed by a surface treatment. After the surface treatment, a dry developing process may be used to form a pattern in the resist layer. As will be described in greater detail below, the dry developing process may include one or both of a plasma process or a thermal process.

Referring now to FIG. 3A, a cross-sectional illustration of a stack 300 is shown, in accordance with an embodiment. In an embodiment, the stack 300 may comprise a substrate 301. The substrate 301 may be similar to the substrate 201 described in greater detail above. An underlayer 305 may be provided over the substrate 301. The underlayer 305 may be similar to the underlayer 205 described in greater detail above.

In an embodiment, a resist layer 330 is provided over the underlayer 305. The resist layer 330 may be a resist layer suitable for photolithography that uses EUV, DUV, or UV electromagnetic radiation 315 exposure. For example, the resist layer 330 may comprise a metal-oxide material composition. The metal may comprise tin or the like. The resist layer 330 may be similar to the resist layer 230 described in greater detail above.

In an embodiment, electromagnetic radiation 315 is directed towards the resist layer 330 in order to form exposed regions 320. The exposure process may be similar to any exposure process described in greater detail herein. In an embodiment, the exposed regions undergo a chemical reaction that renders the exposed region more chemically inert than the unexposed regions of the resist layer 330. As such, a subsequent developing process can preferentially remove the unexposed regions of the resist layer 330, as will be described in greater detail below.

Referring now to FIG. 3B, a cross-sectional illustration of the stack 300 at a subsequent processing operation is shown, in accordance with an embodiment. As shown, a surface treatment 319 is applied to the resist layer 330. The surface treatment 319 may preferentially alter the unexposed regions of the resist layer 330 to form treated regions 331. The treated regions 331 may have an increased etch selectivity to the exposed regions 330, compared to an untreated resist layer 330. As such, the developing process can be implemented more successfully.

In an embodiment, the surface treatment 319 may comprise a fluorination process. For example, a gas comprising fluorine may be flown over the resist layer 330. Due to the higher chemical reactivity of the unexposed regions of the resist layer 330, the unexposed regions of the resist layer 330 will be more likely to integrate the fluorine into the material. In some embodiments, fluorine atoms may replace hydrogen atoms in the structure.

Referring now to FIG. 3C, a cross-sectional illustration of the stack 300 at a subsequent processing operation is shown, in accordance with an embodiment. FIG. 3C illustrates the dry develop of the resist layer 330. As shown, a dry develop process 317 is executed, as indicated by the arrow. The dry develop process 317 may include one or more different types of treatments.

In a first embodiment, the dry develop process 317 is a thermal process. The thermal develop process 317 may be similar to any of the thermal processes described in greater detail herein. In an additional embodiment, the dry develop process 317 is a plasma based process. The plasma based develop process 317 may be similar to any of the plasma based processes described in greater detail herein. In yet another embodiment, a hybrid process that combines the use of a thermal process and a plasma process may be used in order to develop the treated resist layer 331. The hybrid process may be similar to any hybrid process described in greater detail herein.

In an embodiment the processing gas (for either a plasma based process, a thermal process, or a hybrid process) may comprise hydrogen (e.g., H₂). In some embodiments, the processing gas comprises only hydrogen. In an embodiment, the developing reaction produces volatile species that can be pumped out of the chamber. For example, when the metal-oxide material comprises tin, the volatile species may include SnH₄, HF, and H₂O. Temperatures, pressures, and other control parameters may be similar to any of those for other dry developing processes described in greater detail herein.

Referring now to FIG. 3D, a cross-sectional illustration of the stack 300 at a subsequent processing operation is shown, in accordance with an embodiment. FIG. 3D illustrates the transfer of the pattern 321 into the substrate 301. In an embodiment, the pattern 321 may be transferred into the substrate 301 by an etching process. A first etching process may remove portions of the underlayer 305, and a second etching process may remove portions of the substrate 301. The etching processes may use a dry etching chemistry (e.g., plasma based processes) or wet etching chemistry. Similar to other embodiments described herein, the develop process and the pattern transfer etching process may be implemented in a single processing chamber.

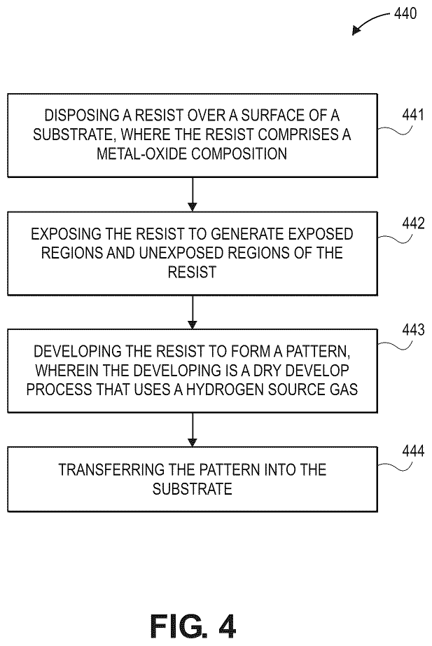

Referring now to FIG. 4, a process flow diagram of a process 440 for developing a resist layer with a dry develop process and transferring the pattern into a substrate is shown, in accordance with an embodiment.

In an embodiment, the process 440 may begin with operation 441, which comprises disposing a resist over a surface of a substrate. In an embodiment, the resist comprises a metal-oxide composition. For example, the metal may comprise tin. In an embodiment, the resist layer may be applied to the substrate with a spin coating process, a deposition process (e.g., CVD, ALD, PVD, etc.), or the like.

In an embodiment, the process 440 may continue with operation 442, which comprises exposing the resist to generate exposed regions and unexposed regions of the resist. The exposure may include exposure to electromagnetic radiation (e.g., EUV, DUV, UV, or the like). The exposure may be done through any of the exposure processes described in greater detail herein. The exposure may result in a chemical reaction in the exposed regions that will produce an etch selectivity between the exposed regions and the unexposed regions.

In an embodiment, process 440 may continue with operation 443, which comprises developing the resist to form a pattern. In an embodiment, the developing is a dry develop process that uses a source gas that comprises hydrogen. In some embodiments, the source gas comprises only hydrogen. In other embodiments, the source gas may comprise hydrogen and one or more inert gasses, such as nitrogen, xenon, argon, or the like.

In an embodiment, the dry develop process may include a thermal developing process. The thermal process may include flowing the processing gas into the chamber while applying thermal energy in order to preferentially drive a chemical reaction between the processing gas and the unexposed regions of the resist layer. In other embodiments, the dry develop process is a plasma based process. In such embodiments, the processing gas is ionized and ionic and/or radical species may preferentially react with the unexposed regions of the resist layer. The dry develop process may also comprise a combination of a thermal process and a plasma process.

In an embodiment, the process 440 may continue with operation 444, which comprises transferring the pattern into the substrate. The pattern may be transferred into the substrate with an etching process, such as a dry etching process or a wet etching process. After the pattern is transferred into the substrate, the resist layer may be removed with any suitable process.

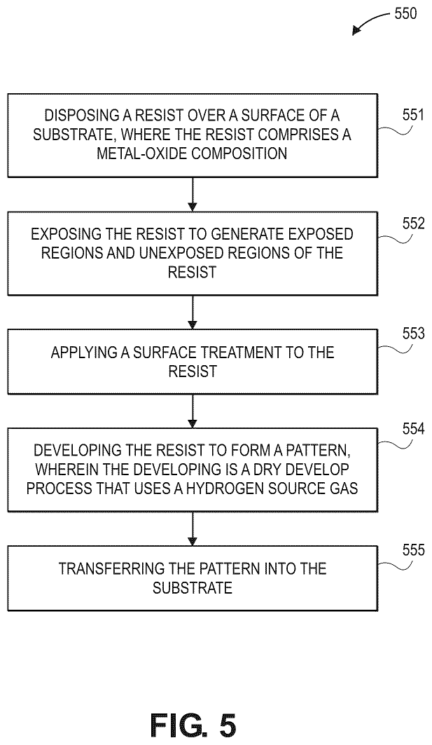

Referring now to FIG. 5, a process flow diagram of a process 550 for developing a resist layer with a dry develop process and transferring the pattern into a substrate is shown, in accordance with an embodiment.

In an embodiment, the process 550 may begin with operation 551, which comprises disposing a resist over a surface of a substrate. In an embodiment, the resist comprises a metal-oxide composition. For example, the metal may comprise tin. In an embodiment, the resist layer may be applied to the substrate with a spin coating process, a deposition process (e.g., CVD, ALD, PVD, etc.), or the like.

In an embodiment, the process 550 may continue with operation 552, which comprises exposing the resist to generate exposed regions and unexposed regions of the resist. The exposure process may be similar to the operation 442 described in greater detail above.

In an embodiment, the process 550 may continue with operation 553, which comprises applying a surface treatment to the resist. In an embodiment, the surface treatment increases the etch selectivity between the exposed regions and the unexposed regions. The surface treatment may be preferentially applied to the unexposed regions since the unexposed regions are more chemically reactive. In some embodiments, the surface treatment is a fluorination treatment.

In an embodiment, process 550 may continue with operation 554, which comprises developing the resist to form a pattern. In an embodiment, the developing is a dry develop process that uses a source gas that comprises hydrogen. In some embodiments, the source gas comprises only hydrogen. In other embodiments, the source gas may comprise hydrogen and one or more inert gasses, such as nitrogen, xenon, argon, or the like. In an embodiment, the developing process may be similar to the dry develop process described above with respect to operation 443. For example, the dry develop process may comprise a thermal develop, a plasma develop, or both a thermal and plasma develop.

In an embodiment, the process 550 may continue with operation 555, which comprises transferring the pattern into the substrate. The pattern may be transferred into the substrate with an etching process, such as a dry etching process or a wet etching process. After the pattern is transferred into the substrate, the resist layer may be removed with any suitable process.

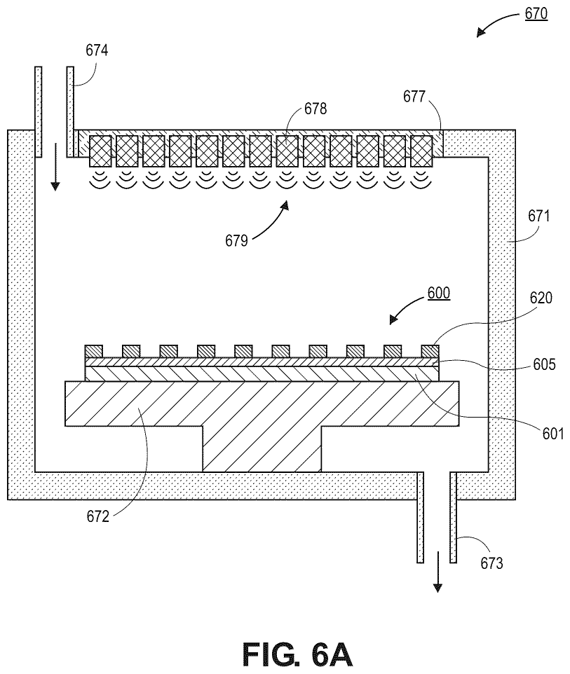

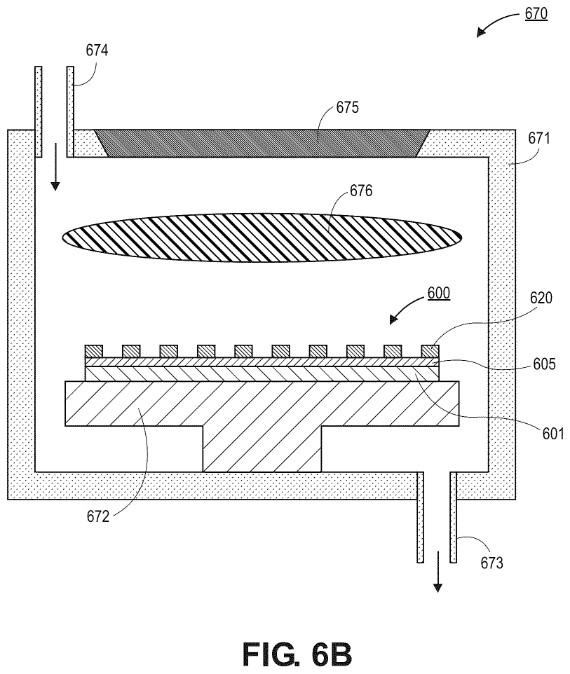

Referring now to FIGS. 6A and 6B, a pair of cross-sectional illustrations depicting different processing tools 670 are shown, in accordance with an embodiment. FIG. 6A is thermal developing chamber, and FIG. 6B is a plasma developing chamber.

Referring now to FIG. 6A, a cross-sectional illustration of a processing tool 670 is shown, in accordance with an embodiment. The tool 670 may include a chamber 671. A pedestal 672 may be provided within the chamber 671 for supporting a stack 600. The stack 600 may be similar to any of the stacks described in greater detail herein. For example, the stack 600 may include a substrate 601, an underlayer 605, and a resist layer 620. An exhaust 673 may be used to set a vacuum pressure and remove gasses and/or byproducts from the chamber 671. In an embodiment, an inlet 674 is provided in order to flow processing gasses into the chamber 671. In an embodiment, a thermal lid 677 is provided at a top of the chamber 671. The thermal lid 677 may house a plurality of lamps 678 (e.g., heat lamps) that can provide thermal energy 679 into the chamber 671 in order to drive a thermal resist developing process.

Referring now to FIG. 6B, a cross-sectional illustration of a tool 670 is shown, in accordance with an additional embodiment. The tool 670 in FIG. 6B may be similar to the tool 670 in FIG. 6A, with the exception of the lid. For example, an electrode 675 or the like may be provided in order to induce RF energy or the like into the chamber 671. The energy may couple with processing gasses (e.g., hydrogen) in order to strike a plasma 676 that can be used to pattern the resist 620.

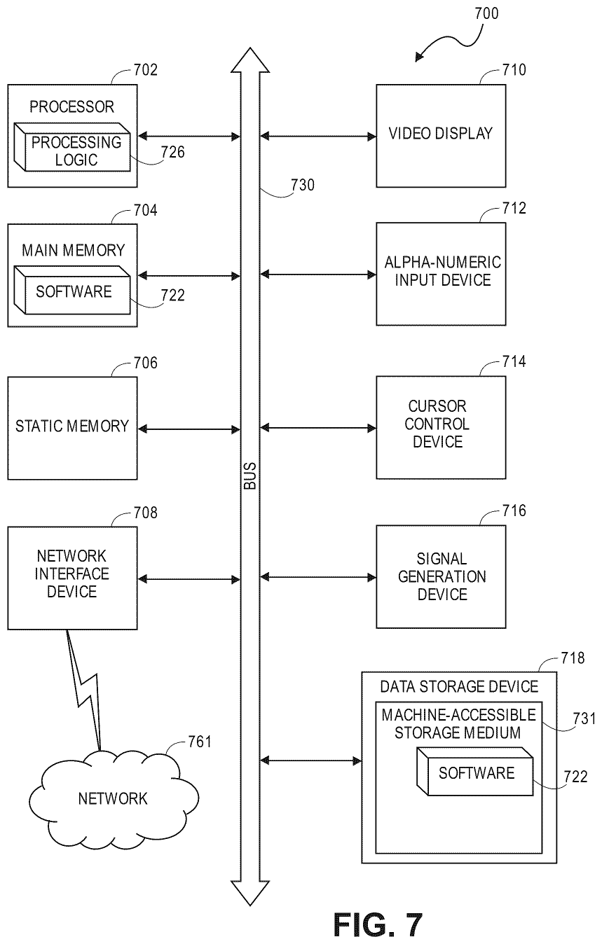

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for developing a resist layer that comprises tin and oxygen with an exposed region and an unexposed region, the method comprising:
applying a surface treatment to the resist layer, wherein the surface treatment incorporates fluorine into the unexposed region; and
developing the resist layer with a dry develop process that comprises a source gas comprising hydrogen, wherein the developed resist layer has an opening through the resist layer.

2. The method of claim 1, wherein a substrate and an underlayer are below the resist layer.

3. The method of claim 1, wherein the dry develop process comprises a plasma process, and wherein the hydrogen is ionized.

4. The method of claim 1, wherein the dry develop process comprises a thermal process.

5. The method of claim 1, wherein the source gas further comprises one or more of nitrogen, xenon, or argon.

6. The method of claim 1, wherein the developing process has a temperature up to 300° C. and/or a pressure up to 550 Torr.

7. The method of claim 1, further comprising:
transferring a pattern of the opening into a substrate under the resist layer.

8. A method for developing a resist layer that comprises a metal and oxygen, wherein the resist layer comprises an exposed region and an unexposed region that comprises fluorine, and wherein the method comprises:
developing the resist layer with a dry process that comprises a hydrogen source gas, and wherein the developing removes the unexposed region to form an opening through a thickness of the resist layer.

9. The method of claim 8, wherein the dry process comprises one or both of a plasma process, and wherein the hydrogen is ionized.

10. The method of claim 8, wherein the dry process is a thermal process.

11. The method of claim 10, wherein the thermal process has temperature up to 300° C. and/or a pressure up to 550 Torr.

12. The method of claim 8, further comprising:
transferring a pattern of the opening into a substrate under the resist layer.

13. The method of claim 8, wherein the metal comprises tin.

14. A non-transitory computer readable medium comprising instructions that, when executed by at least one processor, cause a processing tool to perform a method for developing a resist layer that comprises a metal and oxygen with an exposed region and an unexposed region, the method comprising:
applying a surface treatment to the resist layer, wherein the surface treatment incorporates fluorine into the unexposed region; and
developing the resist layer with a dry develop process that comprises a source gas comprising hydrogen, wherein the developed resist layer has an opening through the resist layer.

15. The non-transitory computer readable medium of claim 14, wherein a substrate and an underlayer are below the resist layer.

16. The non-transitory computer readable medium of claim 14, wherein the dry develop process comprises a plasma process, and wherein the hydrogen is ionized.

17. The non-transitory computer readable medium of claim 14, wherein the dry develop process comprises a thermal process.

18. The non-transitory computer readable medium of claim 14, wherein the source gas further comprises one or more of nitrogen, xenon, or argon.

19. The non-transitory computer readable medium of claim 14, wherein the developing process has a temperature up to 300° C. and/or a pressure up to 550 Torr.

20. The non-transitory computer readable medium of claim 14, wherein the method further comprises:
transferring a pattern of the opening into a substrate under the resist layer.
